(19) United States
(12) Patent Application Publication
(10) Pub. No.: US 2007/0182455 A1
(43) Pub. Date: Aug. 9, 2007

(54) AND type match circuit structure for content-addressable memories

(76) Inventors: Jinn-Shyan Wang, Chia-Yi (TW); Hung-Yu Li, Chia-Yi (TW); Chia-Cheng Chen, Chia-Yi (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/349,187

(22) Filed: Feb. 8, 2006

(51) Int. Cl. H03K 19/096

(52) U.S. Cl. 326/97

(57) ABSTRACT

This invention provides An AND type match circuit structure for content-addressable memories adopting the Pseudo-Footless Clock-and-Data Pre-charged Dynamic circuit as an AND type match circuit structure, which comprises a plurality of circuit stages. Each circuit stage connects a CMOS to a plurality of NMOS in series, wherein the CMOS is connected to the input of an inverter and a PMOS that is in parallel to the inverter, and the output of the inverter is connected to the CMOS gate of the next circuit stage. The output of the last stage inverter on the Pseudo-Footless Clock-and-Data Pre-charged Dynamic circuit is connected to an AND gate logic circuit. When the AND type match circuit structure is applied to the content-addressable memories of low power consumption and high match speed, the circuit structure is able to increase match speed significantly, and to develop the compiler for the content-addressable memories

### BACKGROUND OF THE INVENTION

1. Field of the Invention

The invention provides an AND type match circuit structure that is applicable to the content-addressable memories, particularly to the AND type match circuit structure using a Pseudo-Footless Clock-and-Data Pre-charged Dynamic (PF-CDPD) circuit.

2. The Prior Arts

The Content Addressable Memory (CAM) is widely used as the lookup table in applications such as a search engine [1], internet router [2] [3], data compression [4], and image processing [5]. A CAM should be pre-stored with an array of data before executing the search operation. When performing a search operation, a new search word is sent into the memory array and is compared simultaneously with all entries of the entire memory array. Depending on search and stored data, one or more matching results will indicate which pre-stored data is a complete match with the input datum. Due to the characteristics of parallel processing for data comparison in each search operation, power consumption is always an important concern when designing CAM circuitry. Due to the continuing shrinkage of the feature size in each generation of the CMOS process, modern applications using CAM demand higher and higher memory capacity, which in turn requires longer and longer memory depth and width. In the face of this demand, improving the search speed is quickly becoming a major challenge in CAM circuit design.

Many works have been devoted to the design of the match-line scheme of CAM to increase the search speed or to reduce the power consumption. The most conventional CAM [6] adopted the classical NOR-logic match line for high search speed, but with the penalty of high power consumption. The design in [7] took advantage of a reduced switching activity from the NAND-type match line to reduce power consumption. However, the price for this is a much degraded search speed because of the native NAND-type logic structure. This speed degradation in turn limits the bit width of each memory entry, which contradicts the requirement of some modern applications such as the lookup table for the IPv6 router, which require a long bit width. The design in [8] tried to solve this problem of bit-width limitation by using the NORA [9] NAND-type match line. However, it did not solve the low-speed problem, and even made it worse because of the utilization of P-type domino gates. The design in [10] went back to the traditional NOR-type match line and employed the concept of suppressing the voltage swing of the match line to reduce the power consumption, and the sense amplifier was adopted for sensing the small voltage swing in order to improve the search speed. The timing control of the “enable” signal of the sense amplifier should be precise enough for the performance. However, the timing control is both critical and difficult considering the PVT variations. The designs in [11] and [12] also used the NOR-type match-line scheme, as well as a more sophisticated closed-loop sensing circuitry for further reducing the voltage swing of the match line so as to reduce the power consumption and improve the search speed. The bias voltage of the sense amplifier in this circuit must be carefully or even adaptively controlled to allow the circuit to work at all the operating corners. The pipelined version of the design in [12] was proposed in [13] for improving the throughput rate. However, the overhead of area and power consumption coming from the flip-flops and the clock driver for pipelining makes this design both hardware and energy inefficient. Recently, a hybrid-type multi-bank CAM architecture [14] was proposed to utilize the high-speed benefit of the NOR-type scheme for bank selection, and to take advantage of the low-power benefit of the NAND-type scheme for each CAM macro block.

### SUMMARY OF THE INVENTION

This invention discloses an AND-type match-line scheme for realizing not only a high-performance but also an energy-efficient content addressable memory. The AND-type match-line is constructed with a new Pseudo-Footless Clock-and-Data Pre-charged Dynamic (PF-CDPD) logic circuit.

The following is to explain the objects, the technical contents, features and the desirable functions of the invention by adopting the preferred embodiments with the attached figures.

### BRIEF DESCRIPTION OF THE DRAWINGS

FIG. 1(a) shows BiCAM cell and FIG. 1(b) shows TCAM cell used in the AND-type match-line scheme.

FIG. 2(a) shows the floor-plan, FIG. 2(b) shows the block diagram of the 11-stage match line, and FIG. 2(c) shows the circuit showing the relationship among the CAM cell, the pseudo-footless gate, and the match line.

FIG. 3 shows the evolution from a domino gate, a CDPD gate, to the PF-CDPD gate.

FIG. 4(a) shows the circuit along the critical-path and FIG. 4(b) shows operating waveforms.

FIG. 5(a) shows the worst-speed evaluation case and FIG. 5(b) shows the pseudo ground effect in this case.

### DETAILED DESCRIPTION OF THE PREFERRED EMBODIMENT

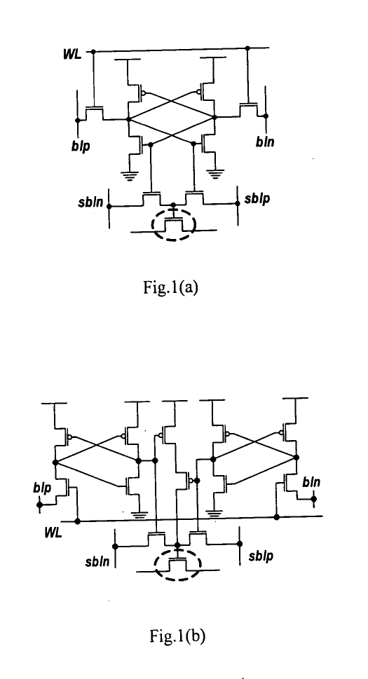

The proposed AND-type match-line scheme can be applied in either the binary CAM (BiCAM) or the ternary CAM (TCAM). The adopted BiCAM and TCAM cells are shown in FIG. 1(a) and FIG. 1(b), respectively. The 9T BiCAM cell is the same as that used in [7], and the 13T CAM cell is derived from the TCAM cell used in [11]. Word-Line (WL) is used for controlling the read or write operations, and is kept low in the search operation. The search bit lines (sblp and sbln) are separated from the read/write bit lines (blp and bln) for reducing the power consumption of the search operation. In both cells, the transistor in the shadow is also the fan-in transistor of the AND-type match-line circuit, which will be explained later. If the TCAM cell needs to perform the “don't care” operation, both storage nodes should be written as “0” to pull up the gate voltage of the shadowed transistor. In the followings, the design of a BiCAM macro with 256 entries and 128 bit per entry is taken as the example to explain the proposed design techniques.

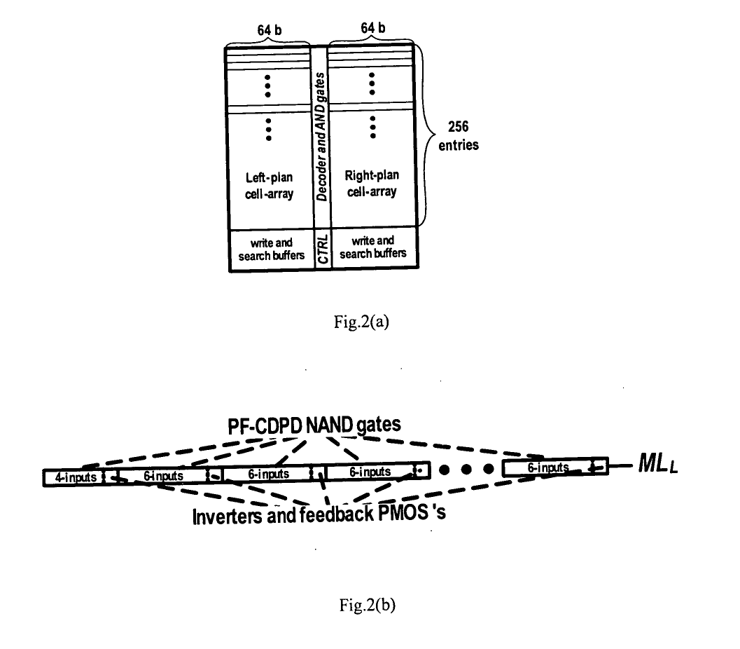

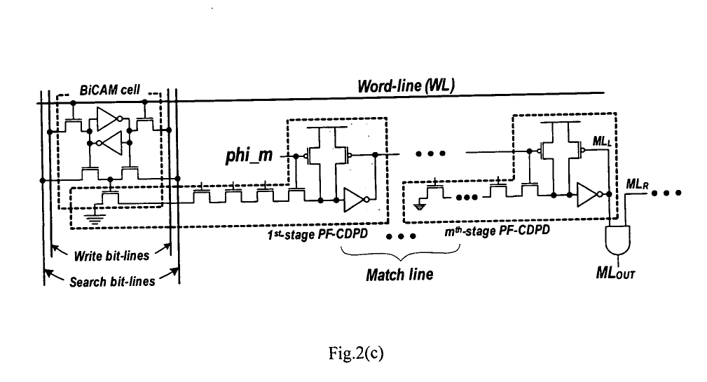

The floor-plan of the designed 256×128-b BiCAM macro is shown in FIG. 2(a). The cell array is partitioned into two half-planes in order to shorten the critical path of the match line. Therefore, the bit width of each half-plane is 64. The 64-b AND-type match line is composed of 11 pseudo-footless AND gates (to be described later) with the block diagram shown in FIG. 2(b). Each pseudo-footless AND gate is composed of a pseudo-footless dynamic NAND gate and a static inverter. The circuit in FIG. 2(c) illustrates the relationship among the CAM cell, the pseudo-footless gate, and the match line. The output of the left match-line and that of the right match-line are connected to a two-input AND gate to generate the final match output MLₒᵤₜ.

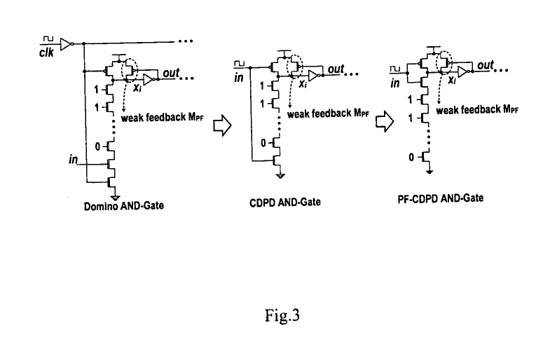

The basic element in the match-line circuit is the proposed pseudo-footless clock-and-data Pre-charged dynamic (PF-CDPD) gate. The operation and the characteristics of the PF-CDPD gate can be understood by describing the evolution from the conventional domino gate [15] and the Clock-and-Data Pre-charged Dynamic (CDPD) gate [16] to the PF-CDPD gate, as shown in FIG. 3. The shaded NMOS and PMOS devices in the domino gate are triggered by a global clock signal. Because the clock signal is sent to all the domino gates, we need a buffer to increase the driving capability of the clock signal. When evolving from the domino gate to the CDPD gate, the global clock signal is only connected to the first CDPD gate of a match line, while all other CDPD gates of the same match line is triggered by the outputs of their preceding gates. Note that the function performed by these two gates is not altered. However, because the external clock signal need not trigger a large load, the size of the clock buffer (not shown) can be largely shrunk. The PF-CDPD gate is evolved a step further from the CDPD gate. The main difference between the CDPD and the PF-CDPD is that the clock- or data-triggered NMOS transistors are placed at different locations. Therefore, CDPD and PF-CDPD still perform the same function, but the timing control style, the performance, and the power consumption are different. The timing control and the operating principle of the CAM macro adopting the AND-type PF-CDPD match circuit is explained below, while the explanation for why the PF-CDPD logic leads to high performance and low power will be described in the next section. Furthermore, the design consideration for overcoming the charge-sharing problem of the PF-CDPD match line will be discussed later in section IV.

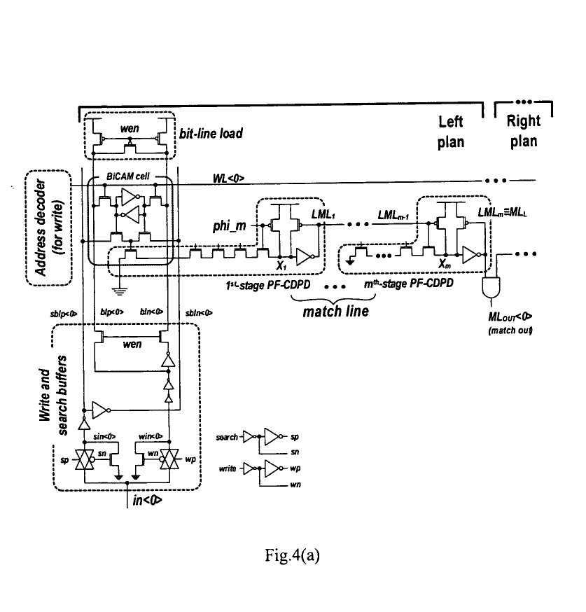

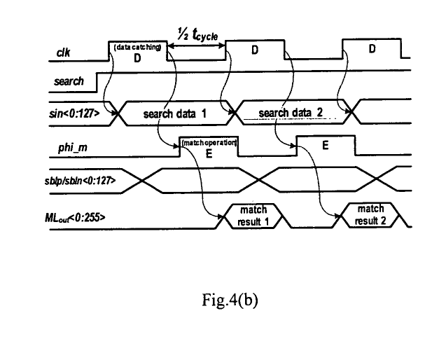

The circuit along the critical path of the designed 256×128-b BiCAM macro is shown in FIG. 4(a). The operating waveforms are illustrated in FIG. 4(b), where clk means the external clock signal (not. shown in FIG. 4(a)). The signal phi₁₃ m is the derived internal clock signal for the match circuit. Each search operation is divided into two phases: data setup and data matching. The dynamic match circuit operates accordingly in two phases as well, i.e. the precharge phase and the evaluation phase. When clk goes high, phi₁₃ m goes low. Now the match circuit enters the precharge phase, and the outputs of every PF-CDPD NAND gate (Xₗ˜Xₘ in FIG. 4(a)) and the local match-lines (LMLₗ˜LMLₘ) are pulled high and low, respectively, by the clock-and-data pre-charging mechanism. At the same time, the input search data (sin<0:127>) are sent in and are passed along all the way to the input of the match circuit through the search bit lines (sblp<0:127> and sbln<0:127>). If the input bit matches with the stored bit, then the PF-CDPD gate will get a high input. If all the inputs of a PF-CDPD gate get a “high”, then the source node of the clocked NMOS will be pulled toward the ground level in this phase, and the pull-down path will remain conductive in the next (evaluation) phase. On the other hand, the pull-down path will be cut off if at least one input gets a “low”. When clk goes low, phi₁₃ m goes high. At that point the search bit lines are kept quiet in this phase, and the match circuit enters the evaluation phase. All the match lines are evaluated at the same time, and the pseudo-footless gates in one match-line are evaluated in domino fashion.

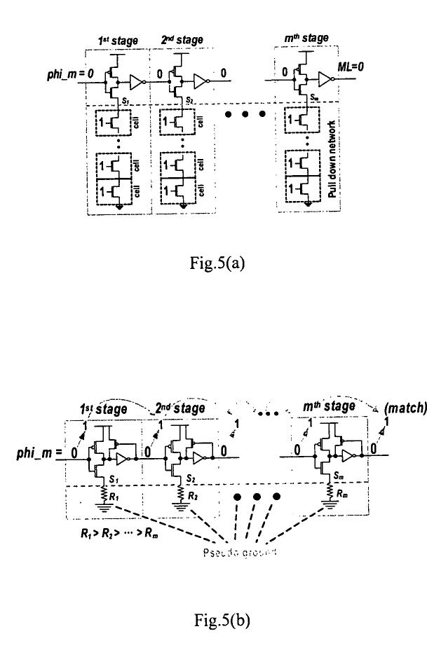

Next, let's see how the PF-CDPD logic contributes to high performance and low power consumption. The worst-speed evaluation happens when the input data fully matches with the stored data. In that case, the evaluation signal will go along the longest path, and the output of each PF-CDPD AND gate of a match line will be pulled high in domino fashion. The status of the match line just before the evaluation phase of this case is illustrated in FIG. 5(a). In that situation, all NMOS transistors in the pull-down networks receive a “high” during the precharge phase, and their drain nodes are being pulled toward the ground level. Therefore, the pull-down network of a particular PF-CDPD AND gate can be electrically replaced with a small resistance when the clock signal for evaluation comes to the gate. The closer the PF-CDPD AND gate to the final match output, the latter it will be evaluated. The latter it is evaluated, the closer its drain node voltage to the ground level at the time of evaluation. We call this phenomenon a pseudo ground effect, and a smaller resistance represents a stronger pseudo ground effect. The PF-CDPD match line now behaves much like a series of inverters with each inverter standing on top of a small resistance, as shown in FIG. 5(b) where R₁>R₂>. . . >Rₘ, and therefore the search time can be greatly reduced. No matter whether a BiCAM or a TCAM is realized with this match-line scheme, the search speed will be nearly the same because of the same critical path with a similar strength of the pseudo ground effect.

The PF-CDPD logic also leads to low power consumption for the following reasons.
(1) In the pre-charge phase, only a small parasitic capacitance at the output node of each dynamic NAND gate is charged. Therefore, if the dynamic gate changes its output state in the evaluation phase, only a small quantity of charges will be pulled to ground, and the power consumption will be small.
(2) The implemented logic function in each PF-CDPD gate is AND. It is well known that a multiple-fan-in AND gate has a low switching activity. Consequently, the average power consumption of a PF-CDPD AND gate is much lower than that of a NOR gate.
(3) The evaluation of the match line (shown in FIG. 4(a)) is started from the left most PF-CDPD gate (or simply called as the first gate). If the first four input bits match completely with the first four stored bits, the output of the first gate will go high after evaluation. The second left most PF-CDPD gate (the second gate) can not begin to evaluate until the output of the first gate goes high. This is because the clock signal of the second gate is exactly the output signal of the first gate. All the following gates have a similar connection way, and then the evaluation of the entire match line will be performed consecutively from the left most gates to the right most gates like a domino. If the output of the first gate is kept low, reflecting an un-matching condition, all the other gates will be kept quiet in the evaluation phase. As such the switching activity of the latter stages is dependent on the evaluation result of the preceding stages. This effect greatly reduces the average switching activity of the match line.
(4) For some applications, the data can be arranged such that the mismatch mostly happens in the left-most bits of FIG. 4(a), so that the average switching activity and the power consumption of the match line, in a statistics sense, can be reduced even further.
(5) As mentioned before, search bit lines are kept quiet in the evaluation phase. Therefore, search bit-lines can be realized as static circuits with no concerns on the data racing or the DC current. Compared to the dynamic counterpart, the static realization of the search circuit saves the switching power.

The above mentioned is only the preferred embodiments of the invention, which is not used to restrict the range of the invention. Therefore, any equivalent modification or decoration from the shape, structure, characteristics and spirit claimed by the invention should be still included in the claims of the invention.

What is claimed:

1. A Pseudo-Footless Clock-and-Data Pre-charged Dynamic circuit comprises a plurality of circuit stages, with each stage being comprised of a dynamic CMOS gate and a static CMOS inverter.

2. The input of the static CMOS inverter as in claim 1 is connected to the output of the dynamic CMOS gate as in claim 1.

3. The Pseudo-Footless Clock-and-Data Pre-charged Dynamic circuit as in claim 1 can also comprise a feedback PMOS, whose drain, gate, and source nodes are connected to the output of the dynamic CMOS gate as in claim 2, the output of the static CMOS inverter as in claim 2, and the power supply, respectively.

4. The dynamic CMOS gate as in claim 1 comprises:
a PMOS device, whose drain, gate, and source nodes are connected to the output of the dynamic gate, the clock input, and the power supply, respectively;
a first NMOS device, whose drain and gate nodes are connected to the output of the dynamic gate and the clock input; and
a NMOS network, which contains a series-connected NMOS devices with the drain node of the top most NMOS device of the NMOS network connected to the source node of the first NMOS device and the source node of the bottom most NMOS device of the NMOS network connected to the ground.

5. Each series-connected NMOS device in the NMOS network as in claim 4 is a NMOS device of a content addressable memory cell of the content addressable memories as in claim 1.

6. The clock input as in claim 4 of the first circuit stage as in claim 1 is connected to the system clock input, and the clock input as in claim 4 of the other circuit stages as in claim 1 is connected to output of the static CMOS inverter as in claim 1 of the previous stage.

7. The output of the static CMOS inverter of the last circuit stage in the AND type match circuit as in claim 1 is the match output of the AND type match circuit as in claim 1.

8. An AND type match circuit structure for content-addressable memories, which comprises:
Several Pseudo-Footless Clock-and-Data Pre-charged Dynamic circuits as in claim 1, with each match output of each Pseudo-Footless Clock-and-Data Pre-charged Dynamic circuit being sent to the input of a multi-input AND gate and the output of the multi-input AND gate is the final match output of the AND type match circuit.
